(19) United States
(12) Patent Application Publication
(10) Pub. No.: US 2025/0123305 A1
(43) Pub. Date: Apr. 17, 2025

(54) ELECTRO-OPTICAL PROBING AND MECHANICAL MICROPROBING OF MEMORY DIE USING A CANTILEVER

(71) Applicant: Micron Technology, Inc., Boise, ID (US)

(72) Inventors: Soeparto Tandjoeng, Boise, ID (US); Takeshi Kaku, Hiroshima (JP); Atsuko Otsuka, Hiroshima (JP)

(21) Appl. No.: 18/784,516

(22) Filed: Jul. 25, 2024

Related U.S. Application Data
(60) Provisional application No. 63/590,992, filed on Oct. 17, 2023.

(51) Int. Cl. G01R 1/067; G01R 31/28; H01L 23/48; H10B 80/00

(52) U.S. Cl. CPC G01R 1/06727; G01R 31/2886; H01L 23/481; H10B 80/00

(57) ABSTRACT

An example apparatus can include a plurality of metal lines. The example apparatus can further include a cantilever, a diode, or a transistor in contact with at least a first metal line and a second metal line of the plurality of metal lines. The example apparatus can further include a circuit comprising at least one transistor or at least one diode in contact with at least the first metal line of the plurality of metal lines. The example apparatus can further include a diode or transistor in contact with at least the second metal line of the plurality of metal lines. An end of the cantilever is in contact with the first metal line through a first via and a first oxide portion. A portion of the cantilever is in contact with the second metal line through a second via and a second oxide portion.

### PRIORITY INFORMATION

This Application claims the benefit of U.S. Provisional Application No. 63/590,992, filed on Oct. 17, 2023, the contents of which are incorporated herein by reference.

### TECHNICAL FIELD

Embodiments of the disclosure relate generally to memory sub-systems, and more specifically, relate to electro-optical probing (EOP) and mechanical microprobing of a memory die using a cantilever.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system in accordance with some embodiments of the present disclosure.

FIG. 2 illustrates an example of an apparatus for electro-optical probing of a memory die using a cantilever in accordance with some embodiments of the present disclosure.

FIGS. 3A-3B each illustrate an example system for performing electro-optical probing and/or mechanical microprobing of a memory die using a cantilever in accordance with some embodiments of the present disclosure.

FIG. 3C illustrates an example system for performing electro-optical probing and/or mechanical microprobing of a memory die using a hybrid cantilever-diode method in accordance with some embodiments of the present disclosure.

FIG. 3D illustrates an example system for performing electro-optical probing and/or mechanical microprobing of a memory die using a hybrid cantilever-transistor method in accordance with some embodiments of the present disclosure.

FIGS. 4A-4B each illustrate an example system for performing electro-optical probing and/or mechanical microprobing of a memory die using a cantilever in accordance with some embodiments of the present disclosure.

FIG. 4C illustrates an example system for performing electro-optical probing and/or mechanical microprobing of a memory die using a hybrid cantilever-diode method in accordance with some embodiments of the present disclosure.

FIG. 4D illustrates an example system for performing electro-optical probing and/or mechanical microprobing of a memory die using a hybrid cantilever-transistor method in accordance with some embodiments of the pre method in accordance with some embodiments of the present disclosure.

FIG. 5 illustrates an example system for performing electrical characterization or electrical programming of a memory die using a cantilever and mechanical microprobing in accordance with some embodiments of the present disclosure.

FIG. 6 illustrates an example system for performing electrical characterization or electrical programming of a memory die using a cantilever and mechanical microprobing in accordance with some embodiments of the present disclosure.

FIG. 7 is a flow diagram of an example method corresponding to electro-optical probing and/or mechanical microprobing of a memory die using a cantilever in accordance with some embodiments of the present disclosure.

FIG. 8 is a block diagram of an example computer system in which embodiments of the present disclosure can operate.

### DETAILED DESCRIPTION

Aspects of the present disclosure are directed to electro-optical probing and/or mechanical microprobing of a memory die using a cantilever. In some examples, the memory die can be one of a multi-die stack of a memory system. A memory sub-system is also hereinafter referred to as a “memory device.” An example of a memory sub-system is a storage system, such as a solid-state drive (SSD). In some embodiments, the memory sub-system is a hybrid memory/storage sub-system. In general, a host system can utilize a memory sub-system that includes one or more memory components. The host system can provide data to be stored at the memory sub-system and can request data to be retrieved from the memory sub-system.

Accessing signals of transistors within a memory die can detect signal transactions and provide a method to determine if the transistors are working properly. In order to provide the signals for detection, a cantilever can be used for guiding a light, such as a laser light, from either a front-side or back-side of the memory die for probing an individual signal, for connecting to an external power supply that can be used to stimulate signals of interest, for on-chip device edits, and/or for on-chip fail-mode simulation. The cantilever can be a Z-shaped cantilever made of a metal material that connects a plurality of metal lines. The metal lines can be connected to the cantilever through vias and/or oxide portions. The oxide portions can initially be insulators that prevent a signal from crossing either from metal line to metal line or from a power supply to one of the metal lines. For instance, light from a laser can be focused on one of the oxide portions to cause the oxide portion to become a conductor. This change in the oxide portion allows a connection through the oxide portion, allowing a power supply to be connected and/or a signal to travel from one metal line to another. The cantilever can allow for probing of an individual signal, connecting to an external power supply that can then be used to stimulate signals of interest, on-chip device edits, and/or on-chip fail mode simulation. In relation to mechanical microprobing, the cantilever can act as a stopper when landing a microprobe or picoprobe tip.

Once a connection is made using the laser approach, and in order to access the signals facilitated by the connection, electro-optical probing (EOP) can be used. EOP can rapidly measure the electrical device activity of a transistor. Electrical device activity, such as signal levels and timing information, can correlate with changes across a p-n junction. Further, for example, when a drain voltage of a FET varies by switching operation, the electric field distribution at a drain boundary can also change. This can cause a change of refractive index due to the electro-optical effect of each material. When irradiating a drain by a light beam or light source through the silicon substrate, the intensity of reflected light varies corresponding to the voltage level. The EOP can observe the reflected light which represents a status of the transistor. It will be appreciated that the light source can be an electromagnetic radiation source that can be configured to generate light (e.g., electromagnetic radiation) that is within the visible light spectrum or is outside the visible light spectrum (e.g., x-ray, extreme ultraviolet, near infrared, mid infrared, far infrared, microwave, radio wave, etc.).

EOP can include using a high intensity light (HIL) source focused on a backside of a memory device. In one example, the light can be beneficial at a particular frequency (e.g., 1300 microns) as the light at that particular frequency can be transparent to silicon. Further, the reflection of the light off of a depletion zone of the memory dies of the memory device can detect the signal transitions. The depletion zone refers to an insulating region within a conductive, doped semiconductor material where the mobile charge carriers have been diffused away, or have been forced away by an electric field. The only elements left in the depletion zone would then be ionized donors or acceptor impurities. This depletion zone of uncovered positive and negative ions can be referred to the depletion zone due to the depletion of carriers in this region. For example, the depletion zone is formed from a conducting region by removal of all free charge carriers, leaving none to carry current. EOP can also use a solid immersion lens (SIL) to resolve individual memory devices. A SIL lens can have a fixed focal length and the thickness of the memory device substrate can be matched with an SIL lens with a same focal length.

Further, in some previous approaches, the presence of dense top metal layers and redistribution layers made it difficult to easily access and quantify the signals for testing using a microprobe pad. As a result, these previous approaches may cause increased capacitance/resistance and hindered probing of high-frequency signals and/or glitches. As described herein below, these shortcomings can be avoided by using a cantilever connected to a via and an oxide portion where the oxide portion can be changed from an insulator to a conductor using light emitted from a laser. In this way, the light from the laser can be used as a type of switch to connect different metal lines to each other or to a power supply. As such, approaches herein can permit the accurate analysis (e.g., as compared to previous approaches which may cause increased capacitance/resistance and thereby may hinder/prevent accurately probing of high-frequency signals and/or result in glitches) of various types of electrical device activity such as signal levels and/or timing information. Yet, the approaches herein do not employ complicated, difficult, and/or expensive analysis techniques in the previous approaches such as those described herein. In addition, the approaches herein can permit defect simulation and/or localization. For instance, in contrast to the prior approaches (e.g., which may rely solely mechanical probing) the approaches described herein can simulate a defect that is physically located within the device (e.g., within a die stack) that would not be otherwise be accessible if merely employing the equipment/methodology of the prior approaches. Alternatively, or in addition, the approaches herein can permit defect localization (e.g., by varying potential differences between metal/signal lines) to accurately located a location of a defect (e.g., a location of a short, a location associated with current leakage, etc.) with a higher degree of granularity than when employing the equipment/methodology of the prior approaches, as described herein. In some embodiments, the approaches herein can be employed in conjunction with and/or as various techniques such as emission microscopy, thermal microscopy, Optical Beam Induced Resistance Change (OBIRCH) and Thermally Induced Voltage Alteration (TIVA), and/or other techniques.

As used herein, “a”, “an”, or “a number of” can refer to one or more of something, and “a plurality of” can refer to two or more such things. For example, a memory device can refer to one or more memory devices, and a plurality of memory devices can refer to two or more memory devices. Further, the figures herein follow a numbering convention in which the first digit or digits correspond to the drawing figure number and the remaining digits identify an element or component in the drawing. Similar elements or components between different figures may be identified by the use of similar digits.

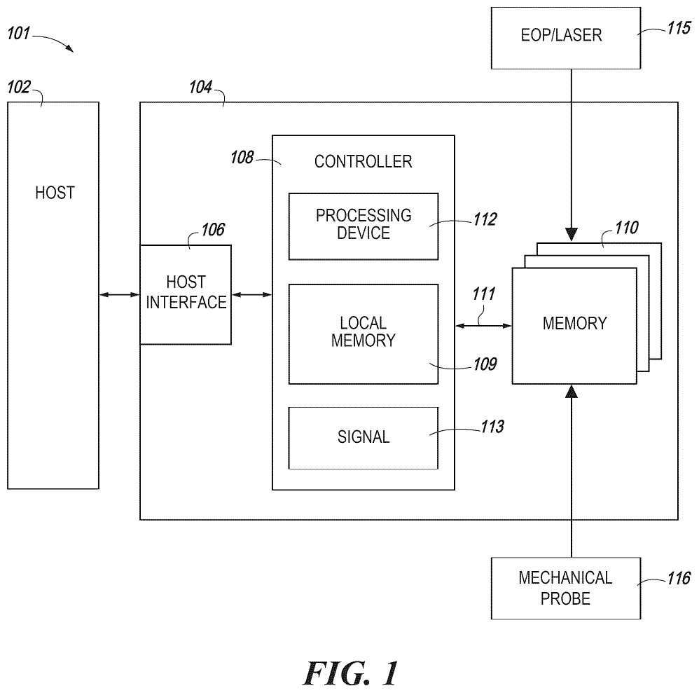

FIG. 1 illustrates an example computing environment 101 that includes a memory sub-system 104 in accordance with some embodiments of the present disclosure. The memory sub-system 104 can include media, such as memory components 110. The memory components 110 can be volatile memory components, non-volatile memory components, or a combination of such. In some embodiments, the memory sub-system is a storage system. An example of a storage system is a SSD. In some embodiments, the memory sub-system 104 is a hybrid memory/storage sub-system. In general, the computing environment 101 can include a host system 102 that uses the memory sub-system 104. For example, the host system 102 can write data to the memory sub-system 104 and read data from the memory sub-system 104.

The host system 102 can be a computing device such as a personal laptop computer, a desktop computer, a digital camera, a mobile telephone, or a memory card reader, among various other types of hosts. The host system 102 can include or be coupled to the memory sub-system 104 (e.g., via a host interface 106) so that the host system 102 can read data from or write data to the memory subsystem 104. As used herein, “coupled to” generally refers to a connection between components, which can be an indirect communicative connection or direct communicative connection (e.g., without intervening components), whether wired or wireless, including connections such as electrical, optical, magnetic, etc. The host interface 106 can be a physical interface, examples of which include, but are not limited to, a serial advanced technology attachment (SATA) interface, a peripheral component interconnect express (PCIe) interface, universal serial bus (USB) interface, Fibre Channel, Serial Attached SCSI (SAS), etc. The host interface 106 can be used to transmit data between the host system 102 and the memory sub-system 104. The host system 102 can further utilize an NVM Express (NVMe) interface to access the memory components 110 when the memory sub-system 104 is coupled with the host system 102 by a PCIe interface. The physical host interface can provide an interface for passing control, address, data, and other signals between the memory sub-system 104 and the host system 102. The memory components 110 can include a number of arrays of memory cells (e.g., non-volatile memory cells). The arrays can be flash arrays with a NAND architecture, for example. However, embodiments are not limited to a particular type of memory array or array architecture. Although floating-gate type flash memory cells in a NAND architecture are generally referred to herein, embodiments are not so limited. The memory cells can be grouped, for instance, into a number of blocks including a number of physical pages. A number of blocks can be included in a plane of memory cells and an array can include a number of planes. As one example, a memory device can be configured to store 8 KB (kilobytes) of user data per page, 128 pages of user data per block, 2048 blocks per plane, and 16 planes per device. The memory components 110 can also include additional circuitry (not illustrated), such as control circuitry, buffers, address circuitry, etc.

In operation, data can be written to and/or read from memory (e.g., memory components 110 of system 104) as a page of data, for example. As such, a page of data can be referred to as a data transfer size of the memory system. Data can be sent to/from a host (e.g., the host system 102) in data segments referred to as sectors (e.g., host sectors). As such, a sector of data can be referred to as a data transfer size of the host.

The memory components 110 can include various combinations of the different types of non-volatile memory components and/or volatile memory components. An example of non-volatile memory components includes a negative-and (NAND) type flash memory. The memory components 110 can include one or more arrays of memory cells such as single level cells (SLCs) or multi-level cells (MLCs) (e.g., triple level cells (TLCs) or quad-level cells (QLCs)). In some embodiments, a particular memory component can include both an SLC portion and a MLC portion of memory cells. Each of the memory cells can store one or more bits of data (e.g., data blocks) used by the host system 102. Although non-volatile memory components such as NAND type flash memory are described, the memory components 110 can be based on various other types of memory such as a volatile memory. In some embodiments, the memory components 110 can be, but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. Furthermore, the memory cells of the memory components 110 can be grouped as memory pages or data blocks that can refer to a unit of the memory component used to store data.

As illustrated in FIG. 1, the memory sub-system 104 can include a controller 108 coupled to the host interface 106 and to the memory components 110 via a memory interface 111. The controller 108 can be used to send data between the memory sub-system 104 and the host system 102. The memory interface 111 can be one of various interface types compliant with a particular standard such as Open NAND Flash interface (ONFi).

The controller 108 can communicate with the memory components 110 to perform operations such as reading data, writing data, or erasing data at the memory components 110 and other such operations. The controller 108 can include hardware such as one or more integrated circuits and/or discrete components, a buffer memory, or a combination thereof. The controller 108 can be a microcontroller, special purpose logic circuitry (e.g., a field-programmable gate array (FPGA), an application-specific integrated circuit (ASIC), etc.), or other suitable processor. The controller 108 can include a processing device 112 (e.g., processor) configured to execute instructions stored in local memory 109. In the illustrated example, the local memory 109 of the controller 108 includes an embedded memory configured to store instructions for performing various processes, operations, logic flows, and routines that control operation of the memory sub-system 104, including handling communications between the memory sub-system 104 and the host system 102. In some embodiments, the local memory 109 can include memory registers storing memory pointers, fetched data, etc. The local memory 109 can also include read-only memory (ROM) for storing micro-code.

While the example memory sub-system 104 in FIG. 1 has been illustrated as including the controller 108, in another embodiment of the present disclosure, a memory sub-system 104 may not include a controller 108, and can instead rely upon external control (e.g., provided by an external host, such as by a processing device separate from the memory sub-system 104).

The controller 108 can use and/or store various operating parameters associated with operating (e.g., programming and/or reading) the memory cells. Such operating parameters may be referred to as trim values and can include programming pulse magnitude, step size, pulse duration, program verify voltages, read voltages, etc. for various different operating processes. The different processes can include processes to program cells to store different quantities of bits, and different multiple pass programming process types (e.g., 2-pass, 3-pass, etc.). The controller 108 can be responsible for other operations such as wear leveling operations, garbage collection operations, error detection and/or correction (e.g., error-correcting code (ECC)) operations, encryption operations, caching operations, and address translations between a logical block address and a physical block address that are associated with the memory components 110.

The memory sub-system 104 can also include additional circuitry or components that are not illustrated. For instance, the memory components 110 can include control circuitry, address circuitry (e.g., row and column decode circuitry), and/or input/output (I/O) circuitry by which they can communicate with the controller 108 and/or the host system 102. As an example, in some embodiments, the address circuitry can receive an address from the controller 108 and decode the address to access the memory components 110.

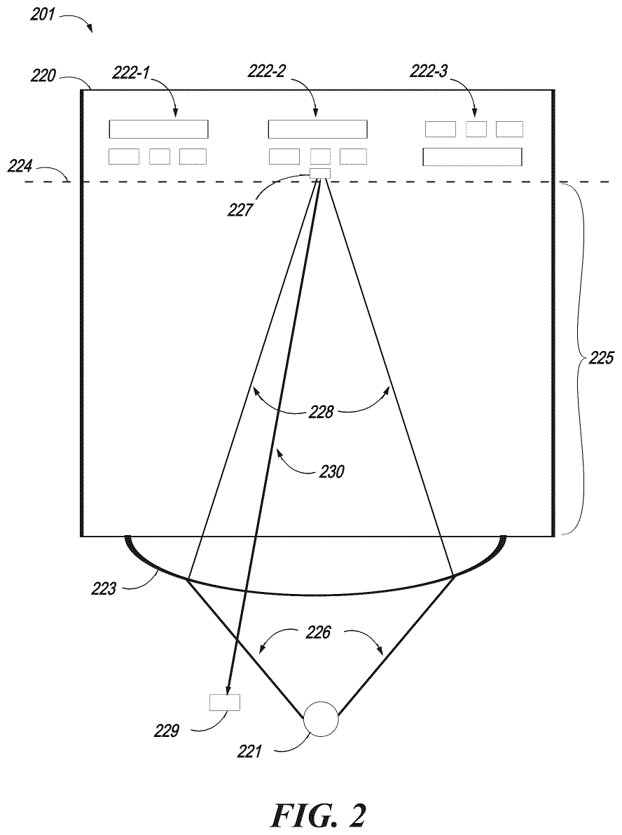

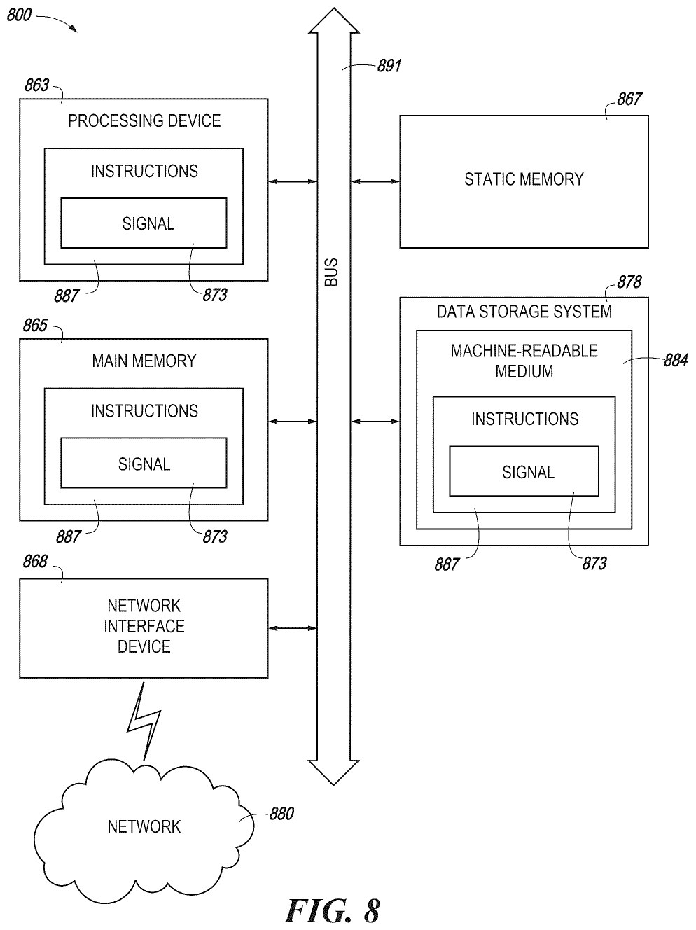

In various embodiments, a signal component 113 (e.g., “SIGNAL” as illustrated in FIG. 1 and FIG. 8.) can be used to gather particular signals and/or perform an EOP operation on the memory components 110, as will be described further below. As an example, the signal component 113 can control switches and/or cause particular signals to be on a particular metal line to test the metal line and thereby permit determination of whether the memory component 110 is working properly. In various embodiments, an electro-optical probing (EOP) component 115 can be used to perform an EOP operation on the memory component 110, as will be described further below. The signal can be detected using an EOP operation. In one example, the EOP operation can include using a laser light or other high-intensity laser light focused on an oxide material which causes the oxide material to change from an insulator to a conductor. Further, in some examples, the EOP operation can include using a light source to direct light at a particular diode and/or transistor of a memory die of a multi-die stack of memory dies in order to determine a signal transition associated with that particular diode and/or transistor. As an example, a signal transition can refer to a transition from one signal state to another signal state. The light source can be a high intensity light (HIL) source. The light can be directed through a SIL in order to direct the light to a particular location within the multi-die stack. The SIL can have a particular fixed focal length. The thickness of the bulk substrate is matched with an SIL lens with a same focal length, as will be described further below in association with FIG. 2. In alternative embodiments, a mechanical probing component 116 can otherwise be used to probe specific internal signals on the memory components 110 as illustrated in FIG. 1 and will be described further below. The signal can be detected using any probe, picoprobe, or microprobe tip. In one example, the mechanical probing operation can include either focusing a laser light or forcing sufficiently high voltage through a direct current probe tip focused onto an oxide material which causes the oxide material to change from an insulator to a conductor.

In various embodiments, the controller 108 can include a signal component 113 to manage, monitor and/or adjust a signal of a particular diode and/or transistor in order to perform an EOP operation. The signal component 113 can be any number of hardware, firmware, and/or additional circuitry to perform the operations described below. For example, the signal component 113 can determine which signal or signal pattern to perform on the targeted diode and/or transistor and send the data indicating the signal or pattern performed to the signal component 113 and/or other external components that use the signal component 113 to perform the EOP operations.

FIG. 2 illustrates an example of a system 201 for electro-optical probing of a plurality of memory dies in accordance with some embodiments of the present disclosure. The system 201 can include a memory device 220, a lens 223, and a light source 221. The memory device 220 can include a plurality of memory dies 222-1, 222-2, 222-3. The memory die 222-2 can include a particular diode and/or transistor 227 used as the target diode and/or transistor. The light source 221 can be a high intensity light (HIL) source. The lens 223 can be a solid immersion lens (SIL). The lens 223 can have a particular fixed focal length. The particular focal length of the lens 223 can correspond to a distance 225 that the lens 223 is from the location 224 of the diode and/or transistor 227.

The light source 221 can emit a portion of light 226 that is directed to the lens 223. The light 226 can be focused through the lens 223 to cause a portion of light 228 to be directed to the diode and/or transistor 227. The portion of light 228 can be reflected off the diode and/or transistor 227. The reflected light 230 can be directed to a sensor 229. The EOP operation can detect the intensity of the reflected light 230 caused by the change in the electric field at the drain of the transistor due to a logic operation being performed. This internal operation can be displayed in a waveform similar to an oscilloscope. The EOP can observe the reflected light 230 which represents the status of the transistor.

In some examples, an electro-optical frequency mapping (EOFM) can be used to image active transistors at a specific frequency. The EOFM can refer to a method of extracting specified frequency components from the reflected light using a spectrum analyzer and mapping the transistors operating at the specified frequency. For EOFM, the reflected light from a drain has a power spectrum distribution. The EOFM can detect the intensity of signal under certain frequency from the frequency distribution and visualize the frequency distribution as an image. By operating transistors in a specific region under certain frequency, it can be possible to observe if the circuits are correctly switching or not.

In some examples, the light source 221 can be a laser. The laser can be used to focus light (a laser beam) emitted from the laser onto the diode and/or transistor 227. Further, the light from the laser can be focused onto a probe pad or other location within the memory die 222-2 for probing a signal. The laser can use a lens 223, as is illustrated in FIG. 2 or the light from the laser may be focused without using a lens. The light from the laser can be focused from the front-side (e.g., from the bottom of illustrated FIG. 2, as is illustrated and described) of the memory die 222-2 or the back-side (e.g., from the top of the illustrated FIG. 2, which is not illustrated here).

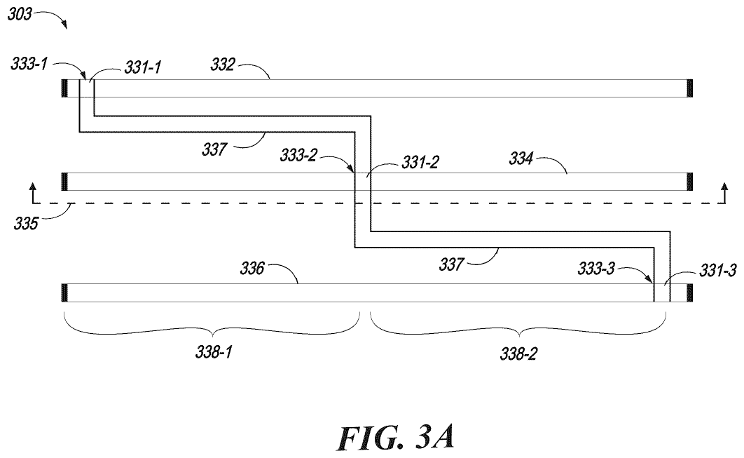

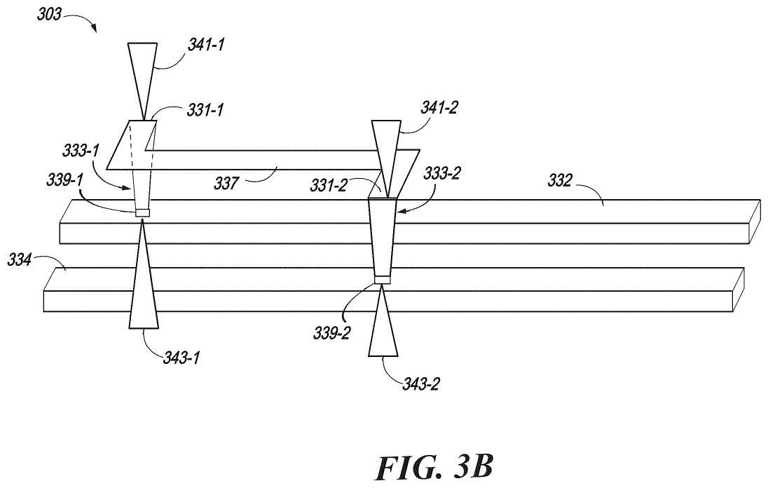

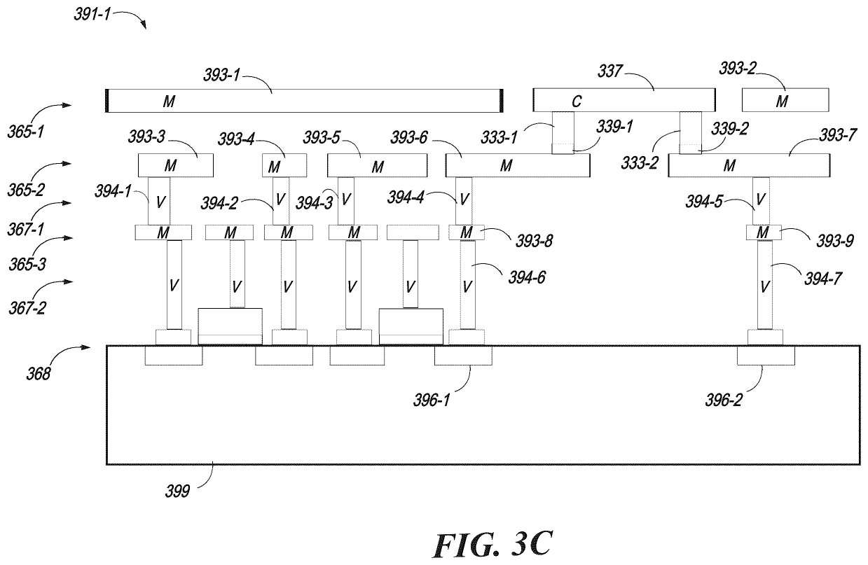

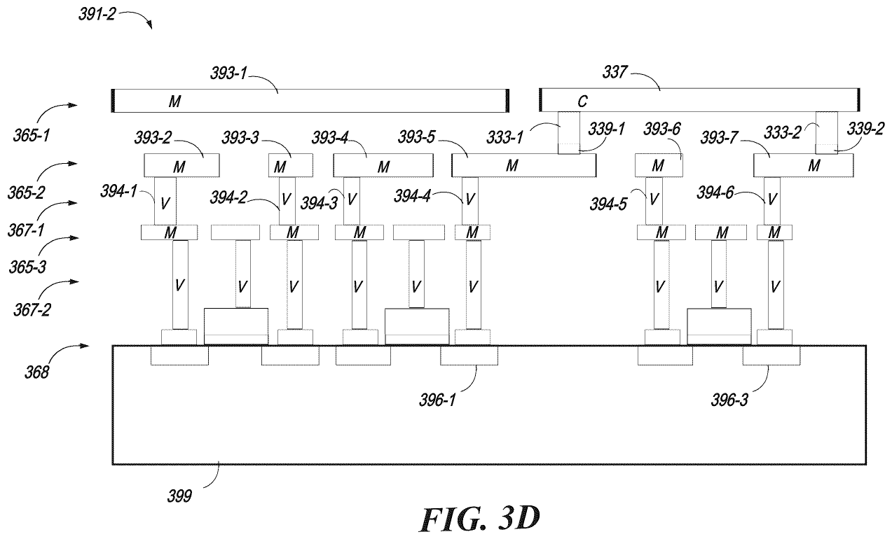

FIG. 3A illustrates a top view of an example system 303 for performing electro-optical probing and/or mechanical microprobing of a memory die using a cantilever 337 in accordance with some embodiments of the present disclosure. The perspective view of FIG. 3A is a top-down view of the system 303. The system 303 can include a plurality of metal lines 332, 334, 336. In some examples, the metal line 332 can be a supply probe pad or Vss (e.g., a ground point or negative power supply). In some examples, the metal line 336 can be a supply probe pad, Vcc or Vccp (e.g., a positive power supply or high positive charge-pump supply). The metal line 334 can be a metal line for testing by connecting to or not connecting to the other metal lines 332, 336.

The cantilever 337 can be connected to each of the plurality of metal lines 332, 334, 336 through a via 333-1, 333-2, 333-3, respectively. For example, a first end 331-1 of the cantilever 337 is connected to the first metal line 332 through a via 333-1. A middle portion 331-2 of the cantilever 337 is connected to the second metal line 334 through a via 333-2. A second end 331-3 (which is opposite the first end 331-1) of the cantilever 337 is connected to the third metal line 336 through a via 333-3. In relation to mechanical probing, the cantilever 337 can act as a stopper when landing a microprobe or picoprobe tip. For example, the Z-shaped curvature of the cantilever 337 can provide a hard corner for the probe tip to rest within to prevent the probe from sliding as the probe is inserted.

In some examples, a distance 338-1 from the first end 331-1 to the middle portion 331-2 can be in the range of 175 nanometers (nm) to 225 nm. In some examples, a distance 338-2 from the middle portion 331-2 to the second end 331-3 can be in the range of 175 nm to 225 nm. In some examples, the distance 338-1 may be equal to the distance 338-2, however examples are not so limited and the distances may vary. A cut line 335 indicates the perspective by which FIG. 3B is illustrated. For example, FIG. 3B is a side view of the system 303 viewed from the cut line 335.

FIG. 3B illustrates a side view of the example system 303 for performing electro-optical probing and/or mechanical microprobing of a memory die using a cantilever 337 in accordance with some embodiments of the present disclosure. The view of the system 303 includes metal lines 332 and 334. In some examples, the metal line 332 can be a supply probe pad or Vss (e.g., a ground point or negative power supply). The metal line 334 can be a metal line for testing by connecting to or not connecting to the other metal lines 332 (and 336 in FIG. 3A). The cantilever 337 can be connected to each of the plurality of metal lines 332, 334 through a via 333-1, 333-2, respectively. For example, a first end 331-1 of the cantilever 337 is connected to the first metal line 332 through a via 333-1. The via 333-1 is in direct contact with an oxide portion 339-1. As used herein, direct contact can refer to an element in contact with another element without any intervening elements. The oxide portion 339-1 is in direct contact with the metal line 332. The oxide portion 339-1 can be an oxide material that acts as an insulator. A middle portion 331-2 of the cantilever 337 is connected to the second metal line 334 through a via 333-2. The via 333-2 is in direct contact with an oxide portion 339-2. The oxide portion 339-2 is in direct contact with the metal line 334. The oxide portion 339-2 can be an oxide material that acts as an insulator. The oxide portion 339-1 and the oxide portion 339-2 can be the same or different oxide materials. In some examples, the oxide portion 339-1 and the oxide portion 339-2 can be the same oxide. Having each of the oxide portions be formed of the same oxide material can ensure that each of the oxide portions is configured to elicit that same/similar response when exposed to the laser light (e.g., laser light at the same frequency, etc.).

In reference to the first end 331-1 of the cantilever 337, a probing element 341-1 can be used to change the oxide portion 339-1 from an insulator to a conductor. In some examples, the probing element 341-1 can be light emitted from a laser that changes the oxide portion 339-1 to the conductor. In some examples, the laser light can have a wavelength in the range of 1340 nm to 1064 nm. In some examples, the probing element 341-1 can be a high-voltage direct current picoprobe or microprobe used to detect a signal on the metal line 332. The probing element 341-1 is used from the front side while an additional probing element 343-1 with similar characteristics as the probing element 341-1 can be used on the back side of the memory die.

In reference to the middle portion of the cantilever 337, a probing element 341-2 can be used to change an oxide portion 339-2 from an insulator to a conductor. In some examples, the probing element 341-2 can be light emitted from a laser that changes the oxide portion 339-2 to the conductor. In some examples, the probing element 341-2 can be a high-voltage direct current picoprobe or microprobe used to detect a signal on the metal line 334. The probing element 341-2 is used from the front side while an additional probing element 343-2 with similar characteristics as the probing element 334-2 can be used on the back side of the memory die.

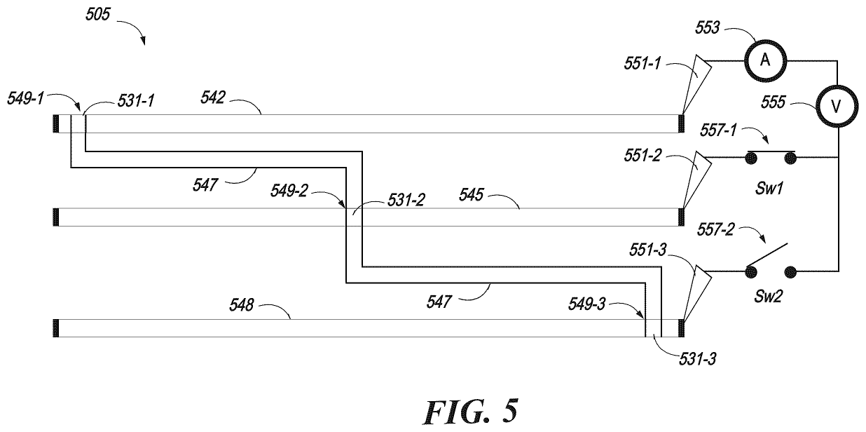

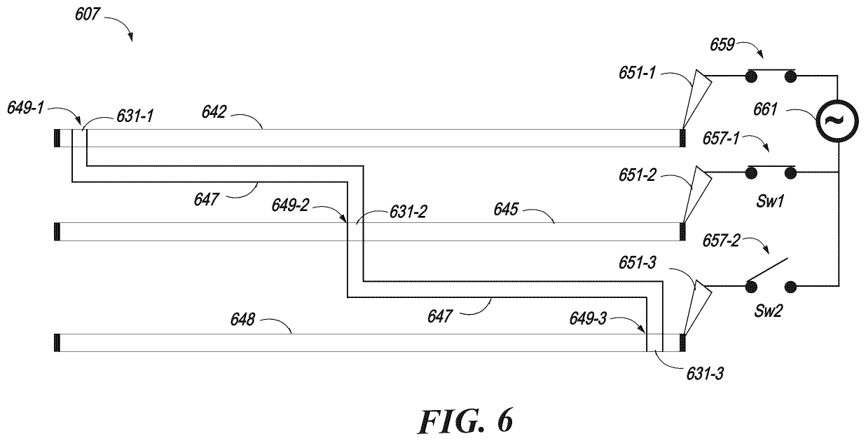

In this way, a number of testing scenarios can be used to determine whether a proper signal is on either of the metal lines 332, 334 and whether unexpected signals or signals transferred in error are occurring, as will be described further in association with FIGS. 5-6. As an example, in the absence of light from a laser being used to turn the oxide portions 339-1, 339-2 into conductors, a lack of signal would be expected if the metal lines 332, 334 were tested with the probing elements 341-1, 341-2 or 343-1, 343-2. Likewise, if light from a laser was directed at both oxide portions 339-1, 339-2 to cause them to conduct and a signal was on either line, it would be expected that the signal would transfer to the other metal line and could be tested to determine if the signal transferred.

FIG. 3C illustrates an example system 391-1 for performing electro-optical probing and/or mechanical microprobing of a memory die using a hybrid cantilever-diode method in accordance with some embodiments of the present disclosure. In one example, the system 391-1 includes a number of rows 365-1, 365-2, 365-3 of metallization layers 393-1, 393-2, 393-3, 393-4, 393-5, 393-6, 393-7 (referred to collectively hereinafter as metallization layers 393, and designated as “M,” where additional metallization “M” layers are illustrated but not labeled for case of reference in the figure). The system 391-1 includes a plurality of vias 394-1, 394-2, 394-3, 394-4, 394-5 (referred to hereinafter collectively as vias 394, and designated as “V,” where additional vias “V” are illustrated but not labeled for ease of reference in the figure) that are respectively connected to each of the metallization layers 393. The system 391-1 includes a row 368 of diodes and/or transistors including a transistor 396-1 and a diode 396-2.

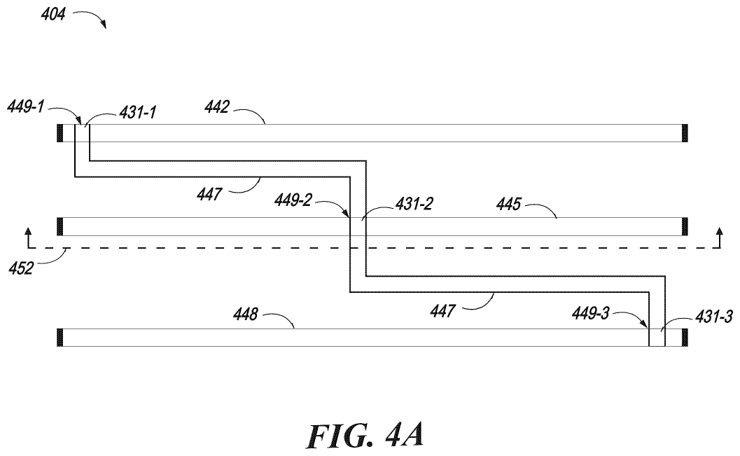

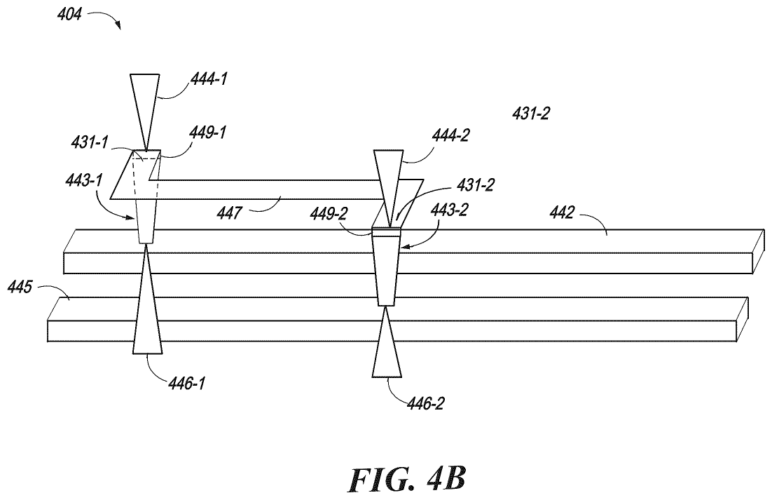

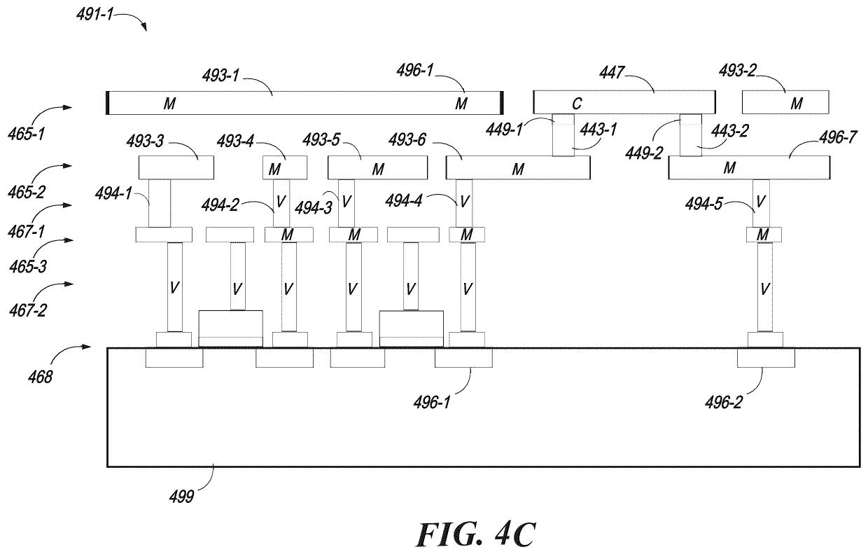

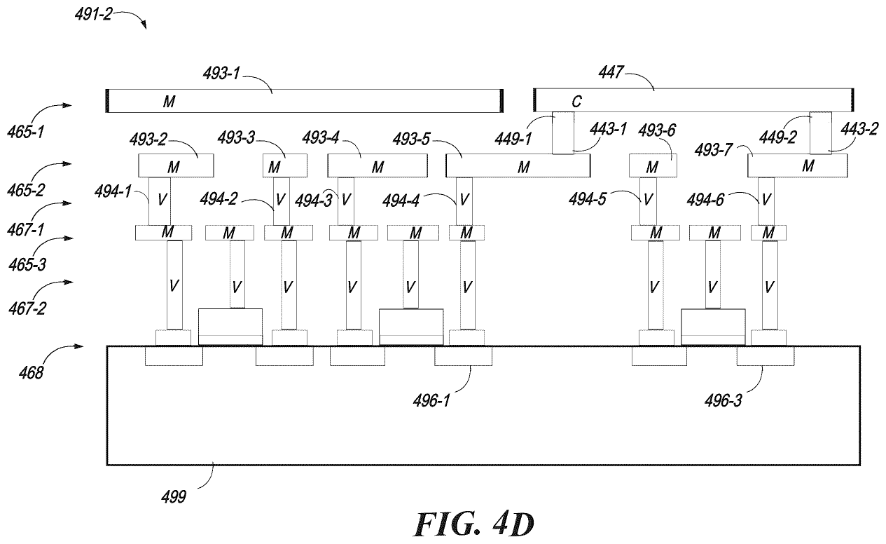

In one example, the system 391-1 includes a cantilever 337, such as the cantilever 337 illustrated in FIGS. 3A-3B, that connects to the metallization layer 393-6 through a via 333-1 and an oxide portion 339-1, as was described in association with FIGS. 3A-3B. As is illustrated in FIG. 3C, the cantilever 337 is in direct contact with the via 333-1 and the oxide portion 339-1 is in direct contact with the metallization layer 393-6 (as opposed to the other way around in association with FIGS. 4C-4D described below). Further, the cantilever 337 connects to metallization layer 393-6 through a via 333-2 and an oxide portion 339-2. In this way, the cantilever 337 connects a target signal generated from a circuit to a diode, e.g., diode 396-2, that is at a distance from the initial transistor, e.g., transistor 396-1, to receive the target signal. This diode structure is used to measure depletion layer thickness correlated with voltage that is applied to it (e.g., signal carried by the cantilever 337). In some examples, an electro-optical probing (EOP) method or a laser voltage probing (LVP) method can be applied to measure this diode 396-2 without interference from peripheral circuits, such as those connected to the other transistors/diodes in the row 368 other than diode 396-2 used for the actual measuring at a distance. As an example, an LVP method refers to an all-optical, contactless and destruction-free fault isolation technique that employs photons to optically measure the electrical device activity, such as signal levels of a switching transistor and corresponding timing information, through the thinned silicon substrate.

FIG. 3D illustrates an example system 391 for performing electro-optical probing and/or mechanical microprobing of a memory die using a hybrid cantilever-transistor method in accordance with some embodiments of the present disclosure. Similar to FIG. 3C, the system 391-2 includes a number of rows 365-1, 365-2, 365-3 of metallization layers 393-1, 393-2, 393-3, 393-4, 393-5, 393-6, 393-7 (referred to collectively hereinafter as metallization layers 393, and designated as “M,” where additional metallization “M” layers are illustrated but not labeled for case of reference in the figure). The system 391-2 includes a plurality of vias 394-1, 394-2, 394-3, 394-4, 394-5, 394-6 (referred to hereinafter collectively as vias 394, and designated as “V,” where additional vias “V” are illustrated but not labeled for ease of reference in the figure) that are respectively connected to each of the metallization layers 393. The system 391-2 includes a row 368 of diodes and/or transistors including a transistors 396-1 and 396-3.

In one example, the system 391-2 includes a cantilever 337, such as the cantilever 337 illustrated in FIGS. 3A-3C, that connects to the metallization layer 393-5 through a via 333-1 and an oxide portion 339-1, as was described in association with FIGS. 3A-3C. As is illustrated in FIG. 3D, the cantilever 337 is in direct contact with the via 333-1 and the oxide portion 339-1 is in direct contact with the metallization layer 393-5 (as opposed to the other way around in association with FIGS. 4C-4D described below). Further, the cantilever 337 connects to metallization layer 393-7 through a via 333-2 and an oxide portion 339-2. In this way, the cantilever 337 connects a target signal generated from a circuit to a transistor (e.g., transistor drain), e.g., transistor 396-3, that is at a distance from the initial transistor, e.g., transistor 396-1, to receive the target signal. This transistor drain structure is used to measure depletion layer thickness correlated with voltage that is applied to it (e.g., signal carried by the cantilever 337). In some examples, an electro-optical probing (EOP) method or a laser voltage probing (LVP) method can be applied to measure this transistor 396-3 without interference from peripheral circuits, such as those connected to the other transistors/diodes in the row 368 other than transistor 396-3 used for the actual measuring at a distance. As an example, an LVP method refers to an all-optical, contactless and destruction-free fault isolation technique that employs photons to optically measure the electrical device activity, such as signal levels of a switching transistor and corresponding timing information, through the thinned silicon substrate.

The cantilever 337 and oxide portions 339-1, 339-2 and vias 333 and 394 enable an amplitude of a power supply or voltage path to be accurately quantified. The EOP or LVP via a distant diode (e.g., diode 396-2) or distant transistor (e.g., transistor 396-3) prevents unwanted interference caused by signal(s) from neighboring circuits (e.g., neighboring diodes and/or transistors) and allows for high resolution signal measurements. The cantilever 337 and distant probing methods enable EOP/LVP and mechanical microprobing to be performed concurrently and applied to a wide range of semiconductor devices. In some examples, vias without oxide portions (or insulators) can be used to permanently connect a target circuit exclusively with a diode or transistor drain placed at a distance through a first metal, a first via, a cantilever, a second via, a second metal, etc. Further, both the cantilever 337 and distant probing methods can enable high-speed signal measurements with high precision and minimal interference and/or distortion.

FIG. 4A illustrates a top view of an example system 404 for performing electro-optical probing and/or mechanical microprobing of a memory die using a cantilever 447 in accordance with some embodiments of the present disclosure. The perspective view of FIG. 4A is a top-down view of the system 404. The system 404 can include a plurality of metal lines 442, 445, 448. In some examples, the metal line 442 can be a supply probe pad or Vss (e.g., a ground point or negative power supply). In some examples, the metal line 448 can be a supply probe pad, Vcc or Vccp (e.g., a positive power supply or high positive charge-pump supply). The metal line 445 can be a metal line for testing by connecting to or not connecting to the other metal lines 442, 448.

The cantilever 447 can be connected to each of the plurality of metal lines 442, 445, 448 through an oxide portion 449-1, 449-2, 449-3, respectively. In some examples, the oxide portions 449-1, 449-2, 449-3 are similar or the same to oxide portions 339-1, 339-2, 338-3 in FIG. 3B. However, in some examples, the oxide portions 449-1, 449-2, 449-3 are different oxide portions than oxide portions 339-1, 339-2, 339-3. Further, for example, a first end 431-1 of the cantilever 447 is connected to the first metal line 442 through an oxide portion 449-1. A middle portion 431-2 of the cantilever 447 is connected to the second metal line 445 through an oxide portion 449-2. A second end 431-3 (which is opposite the first end 431-1) of the cantilever 447 is connected to the third metal line 448 through an oxide portion 449-3. A cut line 452 indicates the perspective by which FIG. 4B is illustrated. For example, FIG. 4B is a side view of the system 404 viewed from the cut line 452.

FIG. 4B illustrates a side view of the example system 404 for performing electro-optical probing and/or mechanical microprobing of a memory die using a cantilever 447 in accordance with some embodiments of the present disclosure. The view of the system 404 includes metal lines 442 and 445. In some examples, the metal line 442 can be a supply probe pad or Vss (e.g., a ground point or negative power supply). The metal line 445 can be a metal line for testing by connecting to or not connecting to the other metal lines 442 (and 448 in FIG. 4A). The cantilever 447 can be connected to each of the plurality of metal lines 442, 445 through oxide portions 449-1, 449-2, respectively. For example, a first end 431-1 of the cantilever 447 is connected to the first metal line 442 through an oxide portion 449-1. The oxide portion 449-1 is in direct contact with a via 443-1. The oxide portions 449-1, 449-2 can each be oxide material that acts as an insulator. The via 443-1 is in direct contact with the metal line 442. A middle portion 431-2 of the cantilever 447 is connected to the second metal line 445 through an oxide portion 449-2. The oxide portion 449-2 is in direct contact with a via 443-2. The via 443-2 is in direct contact with the metal line 445.

In reference to the first end 431-1 of the cantilever 447, a probing element 444-1 can be used to change the oxide portion 449-1 from an insulator to a conductor. In some examples, the probing element 444-1 can be light emitted from a laser that changes the oxide portion 449-1 to the conductor. In some examples, the probing element 444-1 can be a high-voltage direct current picoprobe or microprobe used to detect a signal on the metal line 442. The probing element 444-1 is used from the front side while an additional probing element 446-2 with similar characteristics as the probing element 446-1 can be used on the back side of the memory die.

In reference to the middle portion 431-2 of the cantilever 447, a probing element 444-2 can be used to change an oxide portion 449-2 from an insulator to a conductor. In some examples, the probing element 444-2 can be light emitted from a laser that changes the oxide portion 449-2 to the conductor. In some examples, the probing element 444-2 can be a high-voltage direct current picoprobe or microprobe used to detect a signal on the metal line 445. The probing element 444-2 is used from the front side while an additional probing element 446-2 with similar characteristics as the probing element 446-1 can be used on the back side of the memory die.

In this way, a number of testing scenarios can be used to determine whether a proper signal is on either of the metal lines 442, 445 and whether unexpected signals or signals transferred in error are occurring, as will be described further in association with FIGS. 5-6. As an example, in the absence of light from a laser being used to turn the oxide portions 449-1, 449-2 into conductors, a lack of signal would be expected if the metal lines 442, 445 were tested with the probing elements 444-1, 444-2 or 446-1, 446-2. Likewise, if light from a laser was directed at both oxide portions 449-1, 449-2 to cause them to conduct and a signal was on either line, it would be expected that the signal would transfer to the other metal line and could be tested to determine if the signal transferred.

FIG. 4C illustrates an example system 491-1 for performing electro-optical probing and/or mechanical microprobing of a memory die using a hybrid cantilever-diode method in accordance with some embodiments of the present disclosure. In one example, the system 391-1 includes a number of rows 465-1, 465-2, 465-3 of metallization layers 493-1, 493-2, 493-3, 493-4, 493-5, 493-6, 493-7 (referred to collectively hereinafter as metallization layers 493, and designated as “M,” where additional metallization “M” layers are illustrated but not labeled for case of reference in the figure). The system 491-1 includes a plurality of vias 494-1, 494-2, 494-3, 494-4, 494-5 (referred to hereinafter collectively as vias 494, and designated as “V,” where additional vias “V” are illustrated but not labeled for ease of reference in the figure) that are respectively connected to each of the metallization layers 493. The system 491-1 includes a row 468 of diodes and/or transistors including a transistor 496-1 and a diode 496-2.

In one example, the system 491-1 includes a cantilever 447, such as the cantilever 447 illustrated in FIGS. 4A-4B, that connects to the metallization layer 493-6 through a via 443-1 and an oxide portion 449-1, as was described in association with FIGS. 3A-3B. As is illustrated in FIG. 4C, the cantilever 447 is in direct contact with the oxide portion 449-1 and the via 443-1 is in direct contact with the metallization layer 493-6 (as opposed to the other way around in association with FIGS. 3C-3D described above). Further, the cantilever 447 connects to metallization layer 493-6 through a via 443-2 and an oxide portion 449-2. In this way, the cantilever 447 connects a target signal generated from a circuit to a diode, e.g., diode 496-2, that is at a distance from the initial transistor, e.g., transistor 496-1, to receive the target signal. This diode structure is used to measure depletion layer thickness correlated with voltage that is applied to it (e.g., signal carried by the cantilever 447). In some examples, an electro-optical probing (EOP) method or a laser voltage probing (LVP) method can be applied to measure this diode 496-2 without interference from peripheral circuits, such as those connected to the other transistors/diodes in the row 468 other than diode 496-2 used for the actual measuring at a distance. As an example, an LVP method refers to an all-optical, contactless and destruction-free fault isolation technique that employs photons to optically measure the electrical device activity, such as signal levels of a switching transistor and corresponding timing information, through the thinned silicon substrate.

FIG. 4D illustrates an example system 491-2 for performing electro-optical probing and/or mechanical microprobing of a memory die using a hybrid cantilever-transistor method in accordance with some embodiments of the present disclosure. Similar to FIG. 4C, the system 491-2 includes a number of rows 465-1, 465-2, 465-3 of metallization layers 493-1, 493-2, 493-3, 493-4, 493-5, 493-6, 493-7 (referred to collectively hereinafter as metallization layers 493, and designated as “M,” where additional metallization “M” layers are illustrated but not labeled for case of reference in the figure). The system 491-2 includes a plurality of vias 494-1, 494-2, 494-3, 494-4, 494-5 (referred to hereinafter collectively as vias 494, and designated as “V,” where additional vias “V” are illustrated but not labeled for ease of reference in the figure) that are respectively connected to each of the metallization layers 493. The system 491-2 includes a row 468 of diodes and/or transistors including a transistors 496-1 and 496-3. In one example, the system 491-2 includes a cantilever 447, such as the cantilever 447 illustrated in FIGS. 4A-4C, that connects to the metallization layer 493-5 through an oxide portion 449-1 and a via 443-1, as was described in association with FIGS. 4A-4C. As is illustrated in FIG. 4D, the cantilever 447 is in direct contact with the oxide portion 449-1 and the via 443-1 is in direct contact with the metallization layer 493-6 (as opposed to the other way around in association with FIGS. 3C-3D described above). Further, the cantilever 447 connects to metallization layer 493-7 through an oxide portion 449-2 and a via 443-2. In this way, the cantilever 447 connects a target signal generated from a circuit to a transistor (e.g., transistor drain), e.g., transistor 496-3, that is at a distance from the initial transistor, e.g., transistor 496-1, to receive the target signal. This transistor drain structure is used to measure depletion layer thickness correlated with voltage that is applied to it (e.g., signal carried by the cantilever 447). In some examples, an electro-optical probing (EOP) method or a laser voltage probing (LVP) method can be applied to measure this transistor 496-3 without interference from peripheral circuits, such as those connected to the other transistors/diodes in the row 468 other than transistor 496-3 used for the actual measuring at a distance. As an example, an LVP method refers to an all-optical, contactless and destruction-free fault isolation technique that employs photons to optically measure the electrical device activity, such as signal levels of a switching transistor and corresponding timing information, through the thinned silicon substrate.

FIG. 5 illustrates an example system 505 for performing electrical characterization or electrical programming of a memory die using a cantilever 547 and mechanical microprobing in accordance with some embodiments of the present disclosure. The perspective view of FIG. 5 is a top-down view of the system 505. The system 505 can include a plurality of metal lines 542, 545, 548 (e.g., similar to metal lines 332, 334, 336 in FIG. 3A-3B and metal lines 442, 445, 448 in FIGS. 4A-4B). In some examples, the metal line 542 can be a supply probe pad or Vss (e.g., a ground point or negative power supply). In some examples, the metal line 548 can be a supply probe pad, Vcc or Vccp (e.g., a positive power supply or high positive charge-pump supply). The metal line 545 can be a metal line for testing by connecting to or not connecting to the other metal lines 542, 548.

The cantilever 547 can be connected to each of the plurality of metal lines 542, 545, 548 through an oxide portion 549-1, 549-2, 549-3, respectively. For example, a first end 531-1 of the cantilever 547 is connected to the first metal line 542 through an oxide portion 549-1. A middle portion 531-2 of the cantilever 547 is connected to the second metal line 545 through an oxide portion 549-2. A second end 531-3 (which is opposite the first end 531-1) of the cantilever 547 is connected to the third metal line 548 through an oxide portion 549-3.

The system 505 includes a plurality of probing elements 551-1, 551-2, and 551-3 (hereinafter referred to collectively as plurality of probing elements 551). The plurality of probing elements 551 can be used to detect and/or measure signals from each or all of the metal lines 542, 545, 548. The setup of the system 505 can include detecting the signals of the metal lines 542, 545, 548 using a 2-terminal or 2-point I-V measurement when two or more metal lines are connected. The first probing element 551-1 can connect the first metal line 542 to the other metal lines 545, 548 through an ammeter (“A”) 553 and a DC power supply and voltmeter (both represented by “V”) 555. An ammeter 553 refers to an instrument for measuring leakage current. The metal line 545 can be connected to the other two metal lines 542, 548 through a first switch (“Sw1”) 557-1. The metal line 548 can be connected to the other two metal lines 542, 545 through a second switch (“Sw2”) 557-2. In this way, the probing elements 551-1, 551-2, 551-3 can connect the metal lines 542, 545, 548 to each other through a DC power supply 555 and switched 557-1, 557-2 to control which metal lines are connected.

As an example, when both the first switch 557-1 and the second switch 557-2 are open, none of the metal lines 542, 545, 548 are connected. When the first switch 557-1 is closed and the second switch 557-2 is open, the two metal lines 542, 545 are connected. When the first switch 557-1 is open and the second switch 557-2 is closed, the two metal lines 542, 548 are connected. And when both of the first switch 557-1 and the second switch 557-2 are closed, all three metal lines 542, 545, 548 are connected. In this way, the signal on each of the metal lines 542, 545, 548 can be detected and determine whether an expected capacitance or voltage are on each of the metal lines 542, 545, 548 or whether there is an error in the system 505.

FIG. 6 illustrates an example system for performing electrical characterization or electrical programming of a memory die using a cantilever and mechanical microprobing in accordance with some embodiments of the present disclosure. The perspective view of FIG. 6 is a top-down view of the system 607. The system 607 can include a plurality of metal lines 642, 645, 648 (e.g., similar to metal lines 332, 334, 336 in FIG. 3A-3B and metal lines 442, 445, 448 in FIGS. 4A-4B). In some examples, the metal line 642 can be a supply probe pad or Vss (e.g., a ground point or a negative power supply). In some examples, the metal line 648 can be a supply probe pad, Vcc or Vccp (e.g., a positive power supply or high positive charge-pump supply). The metal line 645 can be a metal line for testing by connecting to or not connecting to the other metal lines 642, 648.

The cantilever 647 can be connected to each of the plurality of metal lines 642, 645, 648 through an oxide portion 649-1, 649-2, 649-3, respectively. For example, a first end 631-1 of the cantilever 647 is connected to the first metal line 642 through an oxide portion 649-1. A middle portion 631-2 of the cantilever 647 is connected to the second metal line 645 through an oxide portion 649-2. A second end 631-3 (which is opposite the first end 631-1) of the cantilever 647 is connected to the third metal line 648 through an oxide portion 649-3.

The system 607 includes a plurality of probing elements 651-1, 651-2, and 651-3 (hereinafter referred to collectively as plurality of probing elements 651). The plurality of probing elements 651 can be used to detect and/or measure signals from each or all of the metal lines 642, 645, 648. The setup of the system 607 can include detecting the signals of the metal lines 642, 645, 648 using a Capacitance-Voltage (C-V) measurement (either by using a C-V meter 661 or a combination of function generators and oscilloscopes) when none or only one of the oxide portions being exposed to laser light and the rest of the oxide portions may not be exposed to light from the laser and/or mechanical probe stimulation. The first probing element 651-1 can connect the first metal line 642 to the other metal lines 645, 648 through a first switch 659. The metal line 645 can be connected to the other two metal lines 642, 648 through a second switch (“Sw1”) 657-1. The metal line 648 can be connected to the other two metal lines 642, 645 through a third switch (“Sw2”) 657-2. In this way, the probing elements 651-1, 651-2, 651-3 can connect the metal lines 642, 645, 648 to each other through a C-V meter 661 (e.g., an AC C-V meter which measures bias voltage and/or capacitance).

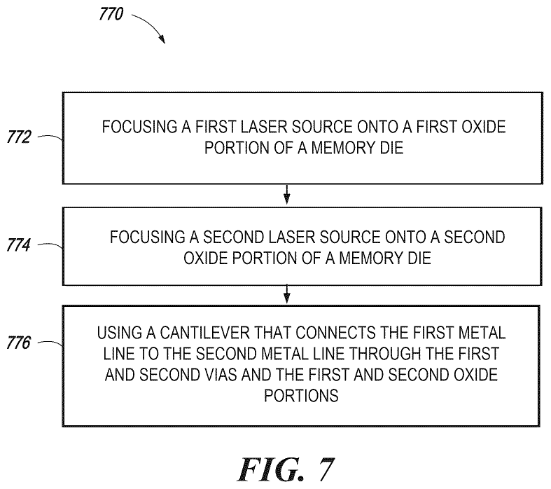

FIG. 7 is a flow diagram of an example method 770 corresponding to electro-optical probing and/or mechanical microprobing of a memory die using a cantilever in accordance with some embodiments of the present disclosure. The method 770 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 770 is performed by the signal component 113, the EOP/Laser component 115, and/or the mechanical probe component 116 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 772, the method 770 can include focusing light from a first laser source onto a first oxide portion of a memory die. In alternative examples, the method 770 can include forcing sufficiently high voltage from a probe tip onto a first oxide portion of a memory die. In some examples, the first oxide portion can be in contact with a first via and a first metal line. The focusing of the light from the laser source or the forcing of sufficiently high voltage from a probe tip onto the first oxide portion causes the first oxide portion to change from an insulator to a conductor.

At block 774, the method 770 can include focusing light from a laser source onto a second oxide portion of a memory die. In alternative examples, the method 770 can include forcing sufficiently high voltage from a probe tip onto a first oxide portion of memory die. In some examples, the second oxide portion is in contact with a second via and a second metal line. The focusing of the light from the laser source or the forcing of the sufficiently high voltage from a probe tip onto the second oxide portion causes the second oxide portion to change from an insulator to a conductor.

In some examples, the method 770 can include detecting an error in one of the first metal line or the second metal line in response to a measurement of the parameter being different than expected. In some examples, in relation to the mechanical microprobing, data can be collected using oscilloscopes and logic analyzer tools. In some examples, the method 770 can include measuring a change in electrical device activity via a diode or a transistor connected to the second metal line in response to the first oxide portion and the second oxide portion each changing to a conductor by an electro-optical probing (EOP) or an electro-optical frequency mapping (EOFM).

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 102 of FIG. 1) that includes, is coupled to, or utilizes a memory sub-system (e.g., the memory sub-system 104 of FIG. 1) or can be used to perform the operations of a controller (e.g., to adjust a parameter associated with programming a memory cell, such as a signal component 113). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 863, a main memory 865 (e.g., read-only memory (ROM), flash memory, dynamic random access memory (DRAM) such as synchronous DRAM (SDRAM) or Rambus DRAM (RDRAM), etc.), a static memory 867 (e.g., flash memory, static random access memory (SRAM), etc.), and a data storage system 878, which communicate with each other via a bus 891.

Processing device 863 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 863 can also be one or more special-purpose processing devices such as an application specific integrated circuit (ASIC), a field programmable gate array (FPGA), a digital signal processor (DSP), network processor, or the like. The processing device 863 is configured to execute instructions 887 for performing the adjustment operations using a window adjustment component 873 (including adjusting a voltage window previously described) and steps discussed herein. The computer system 800 can further include a network interface device 868 to communicate over the network 880.

The data storage system 878 can include a machine-readable storage medium 884 (also known as a computer-readable medium) on which is stored one or more sets of instructions 887 or software embodying any one or more of the methodologies or functions described herein. The instructions 887 can also reside, completely or at least partially, within the main memory 865 and/or within the processing device 863 during execution thereof by the computer system 800, the main memory 865 and the processing device 863 also constituting machine-readable storage media. The machine-readable storage medium 884, data storage system 878, and/or main memory 865 can correspond to the memory sub-system 104 of FIG. 1.

In one embodiment, the instructions 887 include instructions to implement functionality corresponding to adjustment of a voltage window (e.g., signal component 113 of FIG. 1). While the machine-readable storage medium 884 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory die, comprising:
a plurality of metal lines;
a cantilever in contact with at least a first metal line and a second metal line of the plurality of metal lines;
a circuit comprising at least one transistor or at least one diode in contact with at least the first metal line of the plurality of metal lines; and
a diode or transistor in contact with at least the second metal line of the plurality of metal lines;
wherein:
an end of the cantilever is in contact with the first metal line through a first via and a first oxide portion;
a portion of the cantilever is in contact with the second metal line through a second via and a second oxide portion; and
the diode or the transistor is located at a distance from the circuit including other transistors and other diodes than the at least one transistor or the at least one diode.

2. The memory die of claim 1, wherein the end of the cantilever is in direct contact with the first via, the first via is in direct contact with the first oxide portion, and the first oxide portion is in direct contact with the first metal line.

3. The memory die of claim 2, wherein the portion of the cantilever is in direct contact with the second via, the second via is in direct contact with the second oxide portion, and the second oxide portion is in direct contact with the second metal line.

4. The memory die of claim 1, wherein the end of the cantilever is in direct contact with the first oxide portion, the first oxide portion is in direct contact with the first via, and the first via is in direct contact with the first metal line.

5. The memory die of claim 4, wherein the portion of the cantilever is in direct contact with the second oxide portion, the second oxide portion is in direct contact with the second via, and the second via is in direct contact with the second metal line.

6. The memory die of claim 1, wherein the first metal line is a supply probe pad.

7. The memory die of claim 1, wherein the first metal line is a ground point.

8. The memory die of claim 1, wherein the second metal line is a power supply voltage.

9. The memory die of claim 1, wherein the second metal line is a ground probe pad.

10. The memory die of claim 1, further comprising a third metal line in contact with an additional end of the cantilever opposite the end through a third via and a third oxide portion.

11. A method, comprising:
focusing light from a first laser source onto a first oxide portion of a memory die, wherein:
the first oxide portion is in contact with a first via and a first metal line; and
the focusing of the light from the first laser source onto the first oxide portion causes the first oxide portion to change from an insulator to a conductor; and
focusing light from a second laser source onto a second oxide portion of a memory die, wherein:
the second oxide portion is in contact with a second via and a second metal line; and
the focusing of the light from second laser source onto the second oxide portion causes the second oxide portion to change from an insulator to a conductor;
wherein a cantilever connects the first metal line to the second metal line through the first via and the second via and the first oxide portion and the second oxide portion.

12. The method of claim 11, further comprising measuring a conductance between the first metal line and the second metal line in response to the first oxide portion and the second oxide portion each changing to the conductor.

13. The method of claim 11, further comprising measuring a voltage between the first metal line and the second metal line in response to the first oxide portion and the second oxide portion each changing to the conductor.

14. The method of claim 11, further comprising measuring a parameter associated with the first metal line and the second metal line, wherein the parameter comprises one of a voltage, current, resistance, conductance, capacitance, electrical device activity, or any combination thereof.

15. The method of claim 11, further comprising measuring a change in electrical device activity via a diode or a transistor connected to the second metal line in response to the first oxide portion and the second oxide portion each changing to a conductor by an electro-optical probing (EOP) or an electro-optical frequency mapping (EOFM).

16. The method of claim 14, further comprising detecting an error in one of the first metal line or the second metal line in response to a measurement of the parameter being different than expected.

17. An apparatus, comprising:
a memory die including a group of memory cells;
wherein the memory die comprises:
a first metal line, a second metal line, and a third metal line; and
a cantilever in contact with the first metal line, the second metal line, and the third metal line, wherein:
a first end of the cantilever is in contact with the first metal line through a first via and a first oxide portion;
a middle portion of the cantilever is in contact with the second metal line through a second via and a second oxide portion; and
a second end, opposite the first end, of the cantilever is in contact with the third metal line through a third via and a third oxide portion.

18. The apparatus of claim 17, comprising a plurality of memory dies arranged in a stack and each including a group of memory cells, and the memory die is one of the plurality of memory dies.

19. The apparatus of claim 17, further comprising a DC power supply connected in parallel with two switches each connected to at least one of the first metal line, the second metal line, and the third metal line.

20. The apparatus of claim 17, further comprising a C-V meter connected in parallel with two switches each connected to at least one of the first metal line, the second metal line, and the third metal line.
